(19) United States
(12) Patent Application Publication
(10) Pub. No.: US 2004/0225800 A1
(43) Pub. Date: Nov. 11, 2004

(54) Wireless network card connectable with SIM card

(76) Inventor: Alan Lin, Hsin Chuang City (TW)

Correspondence Address: Alan LIN, P.O. Box 4-67, Hsin Chuang, Taipei, 242, TW

(21) Appl. No.: 10/434,990

(22) Filed: May 6, 2003

(51) Int. Cl. H05K 7/10; G06F 13/00

(52) U.S. Cl. 710/301

(57) ABSTRACT

A wireless network card device includes a processing device, an interface coupled to the processing device for coupling to a computer facility, a subscriber identify module (SIM) coupler coupled to the processing device, and an SIM card member selectively coupled to the SIM coupler. An antenna may further coupled to the processing device of the wireless network card device via a wireless circuit, for allowing the wireless network card device to be easily communicated with various wireless network systems that may be provided or opened by various or different ISPs.

### BACKGROUND OF THE INVENTION

1. Field of the Invention

The present invention relates to a wireless network card device, and more particularly to a wireless network card device having a subscriber identify module (SIM) card connectable thereto for coupling to or for communicating with various wireless network systems.

2. Description of the Prior Art

For allowing various end users to be coupled to or to be communicated with various wireless network systems, a number of personal or private internet service provider (ISP) have been established and opened to the public or the end users. However, the ISPs are mostly personal or private and each may provide different service items, ranges, characteristics, and may cost different fees to the end users. The ISPs are generally separated into two different kinds.

For example, for one kind of the ISPs that is located in a predetermined or particular area, the end users have to rent a predetermined wireless network card device from either of the ISPs, before the end users may be coupled to or communicated with various wireless network systems; and the predetermined wireless network card device is particularly designed for the predetermined or particular area only, and may not be used in the other areas.

For the other kind of the ISPS, the end users may provide the predetermined wireless network card devices by themselves, but have to rent an account and/or a password from either of the ISPs that is located in a predetermined or particular area, before the end users may be coupled to or communicated with various wireless network systems.

Accordingly, due to poor services provided by the personal or private ISPs, or when the information provided by the ISPs is short, the end users may have to be coupled to the other ISPs. However, the end users may have to rent the predetermined wireless network card devices from the other ISPs, or may have to rent the further accounts and/or passwords from the other ISPs, and thus may have to adapt themselves to the other ISPs.

The present invention has arisen to mitigate and/or obviate the afore-described disadvantages of the conventional wireless network card devices.

### SUMMARY OF THE INVENTION

The primary objective of the present invention is to provide a wireless network card device including a subscriber identify module (SIM) card member connectable thereto for allowing the end users to be coupled to or to be communicated with various wireless network systems provided or opened by various or different ISPs.

In accordance with one aspect of the invention, there is provided a wireless network card device comprising a processing device, an interface coupled to the processing device, for coupling to a computer facility, a subscriber identify module (SIM) coupler coupled to the processing device, and an SIM card member selectively coupled to the SIM coupler, for communicating with various wireless network systems that may be provided or opened by various or different ISPs.

The wireless network card device may further include an antenna coupled thereto for communicating with the wireless network systems, and may further include a wireless circuit coupled between the antenna and the processing device.

Further objectives and advantages of the present invention will become apparent from a careful reading of the detailed description provided hereinbelow, with appropriate reference to the accompanying drawings.

### BRIEF DESCRIPTION OF THE DRAWINGS

FIG. 1 is a schematic view of illustrating the operation of a wireless network card device in accordance with the present invention;

FIG. 2 is a plan schematic view of the wireless network card device;

FIG. 3 is a block diagram illustrating the operation of the wireless network card device; and

FIG. 4 is a block diagram similar to FIG. 3, illustrating the further operation of the wireless network card device.

### DETAILED DESCRIPTION OF THE PREFERRED EMBODIMENT

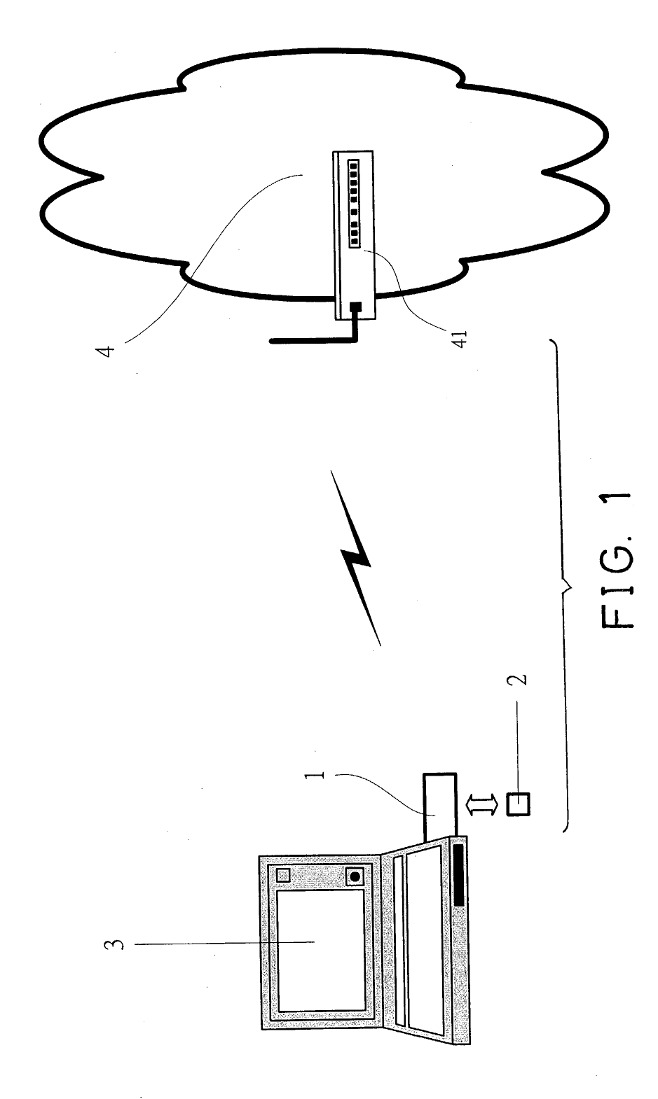

Referring to the drawings, and initially to FIG. 1, a wireless network card device 1 in accordance with the present invention is provided for plugging or coupling to a computer facility 3, and comprises a subscriber identify module (SIM) card 2 connectable thereto for coupling to or for communicating with various wireless network systems 4.

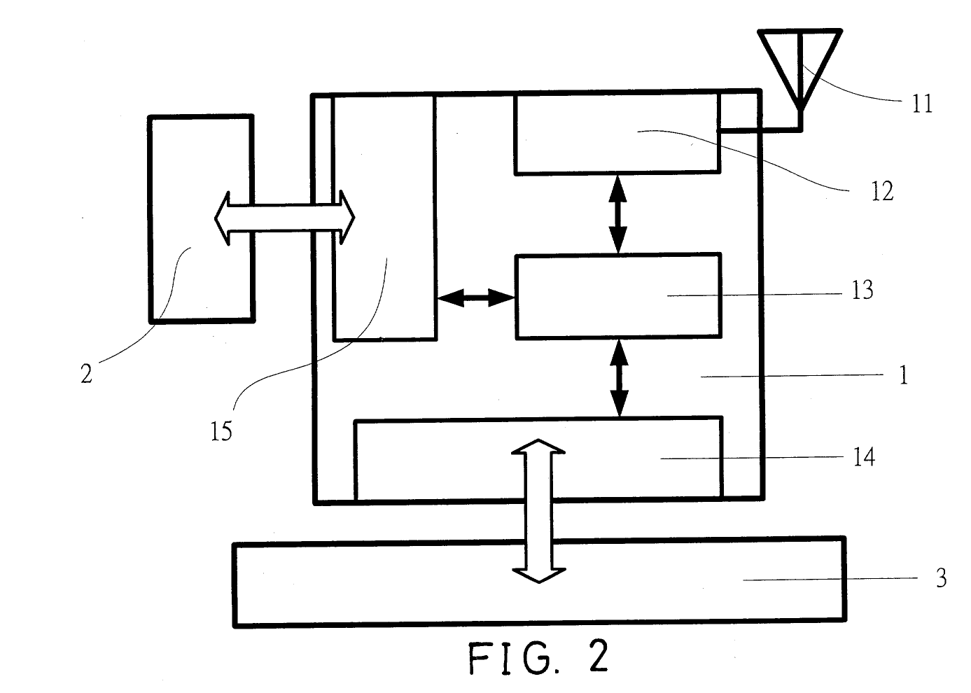

Referring next to FIG. 2, illustrated is a plan schematic view of the wireless network card device 1 which includes a microprocessor or a processing device 13 for receiving and processing and sending various signals, a wireless module or circuit 12 coupled to the processing device 13, and an antenna 11 coupled to the wireless circuit 12, for wirelessly communicating with the wireless network systems 4.

For example, the antenna 11 and the wireless circuit 12 may be used to receive and/or convert various wireless signals, and to send the wireless signals to the processing device 13, and to transmit signals or information from the processing device 13 out to the wireless network systems 4 or the like, for allowing signals or information to be wirelessly communicated between the processing device 13 and the wireless network systems 4.

The wireless network card device 1 includes an interface 14 coupled to the processing device 13, for plugging or coupling to the computer facility 3. For example, the interface 14 may either be a personal computer memory card international association (PCMCIA) interface, a universal serial bus (USB) interface, or the like, for allowing the wireless network card device 1 to be communicated with the computer facility 3.

The wireless network card device 1 further includes an SIM coupler 15 coupled to the processing device 13, for allowing an SIM card member 2 to be coupled to the wireless network card device 1, and thus for allowing the SIM card member 2 to be communicated with the processing device 13 of the wireless network card device 1, and thus to be communicated with the computer facility 3.

The SIM card member 2 includes the predetermined or fixed internet protocol (IP) account that is provided by the ISP. A number of other users may use the predetermined or fixed internet protocol (IP) account of the end user to detect the connection of the end user with the wireless network systems 4, and thus for allowing the end user and the other users to be easily communicated with each other and to share various data and/or images and/or information with each other.

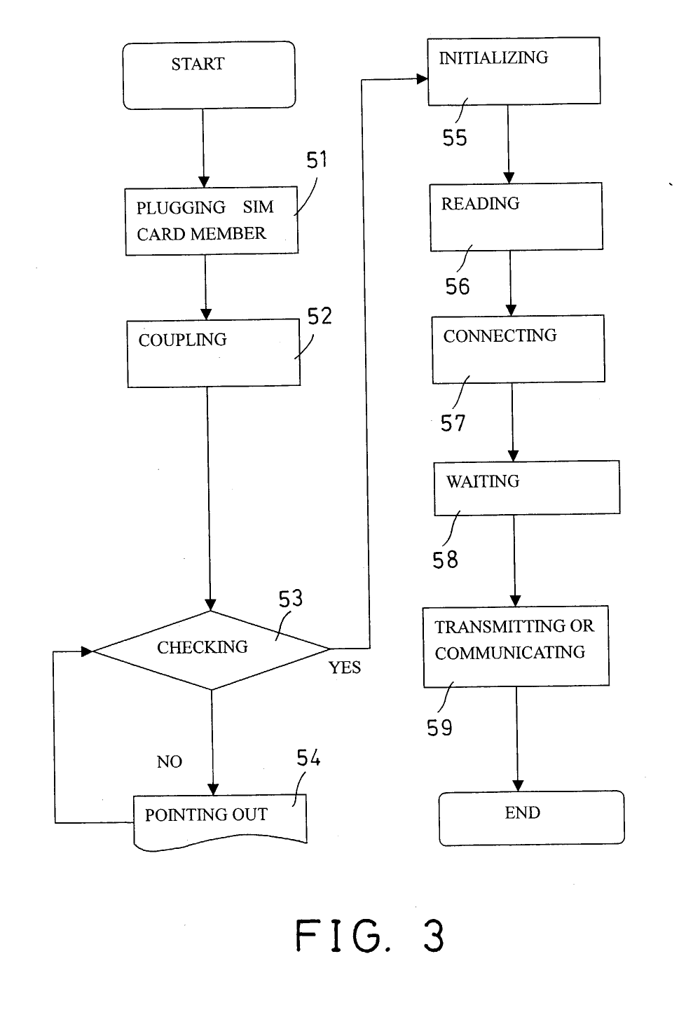

In operation, or while the end user or the computer facility 3 is to communicate with the wireless network systems 4, as shown in FIG. 3, an SIM card member 2 may first be coupled or plugged to the SIM coupler 15 of the wireless network card device 1 in the plugging process 51, and the wireless network card device 1 is then plugged or coupled to the computer facility 3 in the coupling process 52.

A checking process 53 will then be operated or conducted in order to check whether a correct SIM card member 2 having the predetermined or fixed IP account is suitably coupler to the wireless network card device 1 or not.

If the SIM card member 2 has not been suitably or correctly coupled to the SIM coupler 15 of the wireless network card device 1, or if the SIM card member 2 do not have the predetermined or fixed IP account, a pointing out process 54 will then be operated or conducted to ask the end user 3 to plug the correct SIM card member 2 having the predetermined or fixed IP account to the wireless network card device 1.

If the SIM card having the predetermined or fixed IP account has been detected to be suitably or correctly coupled to the SIM coupler 15 of the wireless network card device 1, an initializing process 55 will be conducted or operated to initialize the SIM card member 2, and a reading process 56 will then be conducted or operated to read or fetch the data or information of the SIM card member 2, such as the IP account, the passwords, the service set identifier (SSID), or the like of the SIM card member 2.

A connecting process 57 will then be conducted or operated to connect the wireless network card device 1 with the wireless network systems 4 and/or to transmit the data or information of the SIM card member 2 to the wireless access device 41 of the wireless network systems 4 (FIG. 1), and have to wait in the waiting process 58 until receiving a confirmation massage or information returned from the wireless access device 41 of the wireless network systems 4.

After receiving the confirmation massage or information returned from the wireless access device 41 of the wireless network systems 4, a transmitting or communicating process 59 may then be conducted or operated to connect or to communicate the end user or the computer facility 3 or the wireless network card device 1 of the end user with the wireless network systems 4, until the transmitting or the communicating between the end user or the computer facility 3 or the wireless network card device 1 of the end user and the wireless network systems 4 has been completed or finished or ended.

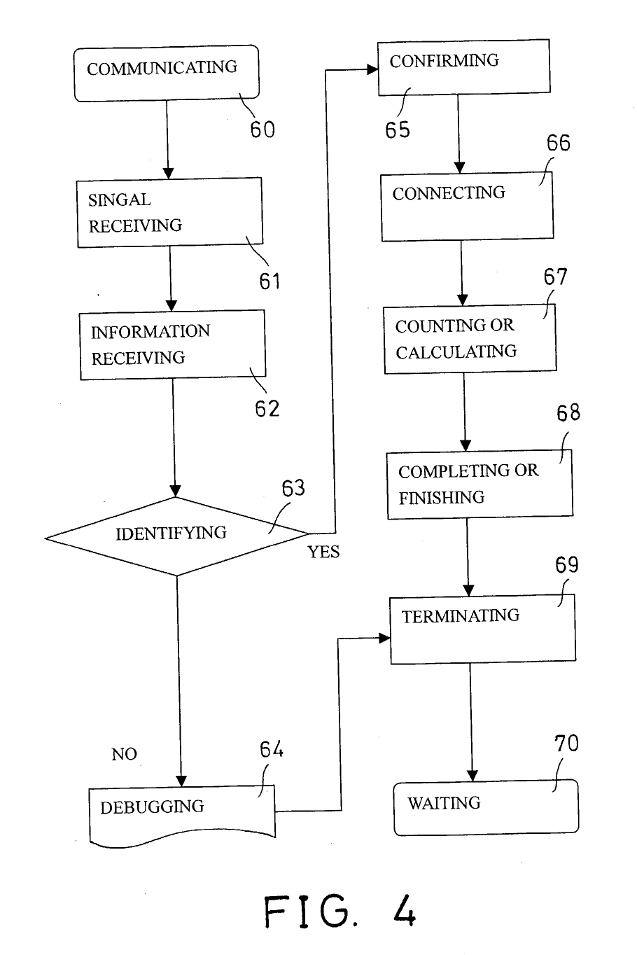

Referring next to FIG. 4, when the wireless access device 41 of the wireless network systems 4 has received the connection or communication signal or request from the wireless network card device 1 in process 60, a signal receiving process 61 may be conducted or operated to receive or to accept the connection or communication signal or request from the wireless network card device 1.

An information receiving process 62 will then be conducted or operated to receive the data or information of the SIM card member 2, such as the IP account, the passwords, the service set identifier (SSID), or the like of the SIM card member 2. An identifying process 63 will then be conducted or operated to check or to examine or to identify whether the information of the SIM card member 2, such as the IP account, the passwords, the service set identifier (SSID), or the like of the SIM card member 2 is correct or acceptable or not.

If the information of the SIM card member 2, such as the IP account, the passwords, the service set identifier (SSID), or the like of the SIM card member 2 has been checked or examined or identified to be wrong or unacceptable, an error detecting or debugging process 64 will then be conducted or operated to check or to detect which of the information is wrong or unacceptable and to send the message back to the wireless network card device 1, and then to conduct or operate a terminating process 69, and then to conduct or operate a waiting process 70, until receiving the connection or communication signal or request from the wireless network card device 1 of the other end users.

On the contrary, if the information of the SIM card member 2, such as the IP account, the passwords, the service set identifier (SSID), or the like of the SIM card member 2 has been checked or examined or identified to be correct or acceptable, a confirming process 65 will then be conducted or operated to send out the confirmation massages or information to the wireless network card device 1.

A connecting process 66 will then be conducted or operated to connect the wireless network systems 4 with the wireless network card device 1 and/or to receive the data or information of the SIM card member 2 to the wireless access device 41 of the wireless network systems 4.

A counting or calculating process 67 will then be conducted or operated to count or to calculate the communication time between the wireless network systems 4 and the wireless network card device 1 and/or the information downloaded from the wireless network systems 4, until receiving a completing or finishing or ending signal or request from the end user or from the wireless network card device 1 in process 68. The terminating process 69 and the waiting process 70 will then be conducted or operated until receiving the further connection or communication signal or request from the wireless network card device 1 of the other end users.

It is to be noted that the end user or the computer facility 3 of the end user may thus be easily and readily coupled to or communicating with various wireless network systems 4 provided or opened by various or different ISPs by the SIM card member 2. The end users may have the predetermined or fixed IP account in the SIM card member 2, and the various or different ISPs may also easily calculate and charge to the owners or the end users of the SIM card member 2.

In addition, a number of other users may thus use the predetermined or fixed IP account of the end user to detect the connection of the end user with the wireless network systems 4, and thus for allowing the end user and the other users to be easily communicated with each other and to share various data and/or images and/or information with each other.

Accordingly, the wireless network card device in accordance with the present invention includes an SIM card member connectable thereto for allowing the end users to be coupled to or to be communicated with various wireless network systems provided or opened by various or different ISPs.

Although this invention has been described with a certain degree of particularity, it is to be understood that the present disclosure has been made by way of example only and that numerous changes in the detailed construction and the combination and arrangement of parts may be resorted to without departing from the spirit and scope of the invention as hereinafter claimed.

I claim:

1. A wireless network card device comprising:
a processing device,
an interface coupled to said processing device, for coupling to a computer facility,
a subscriber identify module (SIM) coupler coupled to said processing device, and
an SIM card member selectively coupled to said SIM coupler, for communicating with various wireless network systems.

2. The wireless network card device as claimed in claim 1 further comprising an antenna coupled thereto for communicating with the wireless network systems.

3. The wireless network card device as claimed in claim 2 further comprising a wireless circuit coupled between said antenna and said processing device.
